(19) United States
(12) Patent Application Publication
(10) Pub. No.: US 2014/0196283 A1
(43) Pub. Date: Jul. 17, 2014

(54) PRESS CUSHION

(71) Applicant: HUECK Rheinische GmbH, Viersen (DE)

(72) Inventor: Rolf Espe, Bochum (DE)

(21) Appl. No.: 14/138,409

(22) Filed: Dec. 23, 2013

(30) Foreign Application Priority Data
Jan. 16, 2013 (DE) 102013100433.4

(51) Int. Cl. B30B 15/06; H05K 3/22

(52) U.S. Cl. CPC B30B 15/061; H05K 3/22
USPC 29/829; 156/580

(57) ABSTRACT

The invention relates to a press cushion for a one level or multi level heating press including a flat contexture made from threads or fibers; and a silicon elastomeric material made by crosslinking silicon rubber and/or a copolymer made by crosslinking silicon rubber and fluor silicon rubber and/or a copolymer made by crosslinking silicon rubber and fluor rubber. In order to overcome quality issues and to comply with stringent cleanliness requirements when producing circuit boards for electrical applications it is proposed that the silicon elastomeric material and/or the copolymer are addition crosslinked.

### RELATED APPLICATIONS

This application claims priority from German application DE 10 2013 100 433.4 filed on Jan. 16, 2013, which is incorporated in its entirety by this reference.

### FIELD OF THE INVENTION

The invention relates to a press cushion for a one- or multi level heated press including
a flat contexture made from threads or fibers; and
silicon elastomeric material made by crosslinking silicon rubber and/or a copolymer produced through crosslinking silicon rubber and fluor silicon rubber and/or a copolymer produced through crosslinking silicon rubber and fluor rubber

### BACKGROUND OF THE INVENTION

Press cushions of this general type are being used for hydraulic one level and multilevel heating presses with and without re-cooling. The presses are used for coating wood material plates with duroplastic or thermoplastic plastic materials.

The functionality of the press cushions arranged between the heating plate and the press plate is very important to achieve equal pressure loading over the entire press blank. Without such press cushions, subsequent warping in the press and thickness tolerances in the pressed material due to manufacturing tolerances would be feasible. Therefore, press cushions have to have sufficient elasticity, this means resiliency in order to be able to compensate thickness tolerances during a pressing process. Additionally they have to have good reset properties after unloading the pressure since the press cushions shall be able to withstand a large number of press cycles in order to prevent frequent replacement of the press cushions.

Another important property of the press cushions is their heat resistance and their heat conductivity, wherein the typical press parameters for one level short cycle presses are temperatures of 200° C. to 220° C., pressures of 250 N/cm² to 500 N/cm² and pressing times of 15 seconds to 25 seconds. High pressure heated presses can even reach pressures of up to 1,000 N/cm² wherein the temperature increases up to 180° C. and press times of up to two hours are being reached.

It is typical for a general type of such press cushions that they are configured from a fabric that includes threads made from elastomeric material and threads made from metal. The metal threads are used for heat transfer from the heating plate to the press plate. Accordingly, the elastomeric threads also have to be high temperature resistant besides having good reset values in order to achieve good cushion properties.

DE 100 32253 A1 describes a press cushion for high pressure applications which is made from a heat resistant cushion material, for example meta-aromatic polyamide fibers. The heat resistant fibers are wrapped around one another through needling which yields an elastic felt type material. In order to improve heat conductivity of such press cushions, an additional fiber with better heat conducting properties, e.g. made from polybenzazole, is used in addition to the meta-aromatic polyamide fibers in EP 1 486 233 A1.

Another known press cushion with chemically resistant properties can be derived from EP 0735949 B1. Press cushions with similar weaving are known for example from EP 1 300 235 B1, EP 1 136 248 A1 or DE 20 2012 005 265 U1. The highly temperature resistant polymeric material of these known press cushions are for example made from a silicon elastomeric material, a fluor elastomeric material and/or a silicon-fluor elastomeric material. The polymeric material is arranged as an enveloping layer about a core thread which can be configured for example as a metal wire or a metal strand but can also be configured as a polymeric thread. While the core thread provides the required longitudinal strength to threads of this type in order to be able to use these threads for example as weft threads in a fabric, the thread jacket made from elastomeric material provides the elasticity required for press cushions of this type and the spring elasticity respectively transversal to the longitudinal thread axis. The elastomeric material is applied on the entire surface of the core thread in a sealed manner through an extrusion process. Thus, the surface is smooth and the circumference of the thread jacket has a substantially circular cross section.

Though excellent crosslinking of the silicon rubbers and copolymers is provided and these types of press cushions can be used in a high temperature range of up to 250° C., the press cushions are not suited for producing one or plural layer plastic plates which are used among other things in the electrical industry, for example CCL copper clad laminates. Furthermore, base materials for producing printed circuit boards for electrical applications, isolation boards for electrical applications, flexible circuit board material, IC card material and all one or plural layer plastic material plates cannot be produced in the known high pressure presses. These types of press cushions cause quality issues for the conductor and circuit boards. Consequently, the finished products cannot comply with pertinent high cleanliness requirements.

### BRIEF SUMMARY OF THE INVENTION

Thus, it is an object of the invention to provide a press cushion which overcomes the quality problems and complies with the high cleanliness requirements when producing conductor and circuit boards for electrical applications.

The object is achieved according to the invention by improving upon a press cushion of the type described supra, in that the silicon elastomeric material and/or the copolymer are addition crosslinked. “Copolymer” designates a copolymer made from silicon rubber and/or fluor silicon rubber and/or a copolymer made from silicon rubber and a fluor rubber.

The object is achieved in particular by a press cushion for a one level or multi level heating press including a flat contexture made from threads or fibers; and a silicon elastomeric material made by crosslinking silicon rubber and/or a copolymer made by crosslinking silicon rubber and fluor silicon rubber and/or a copolymer made by crosslinking silicon rubber and fluor rubber, wherein the silicon elastomeric material and/or the copolymer are addition crosslinked.

The materials made from silicon or its copolymers provided in the conventional form for press cushions were produced through crosslinking with peroxides. This robust method which leads to reliable crosslinking can be performed completely without catalysts. Thus, a peroxide decomposition initially forms free radicals which in turn cause a crosslinking reaction in the silicon rubber. Heat resistance is additionally excellent for this type of crosslinking so that the known press cushions can be used for a temperature range up to 250° C.

As recited supra, the known press cushions cause substantial quality problems when manufacturing printed circuit boards. Precipitations were found over and over again on the printed circuit boards which lead to contaminations which cause short circuits in electronic devices and circuits. These contaminations, however, cannot be easily removed from the circuit boards. It was found that the precipitations are caused by gassing of decomposition products of the peroxides which are arranged in the peroxide crosslinked press cushion. In particular in heating presses with re-cooling which cool the pressing material back down to room temperature at the end of the process, the gassing leads to precipitation on the pressing material caused by condensation.

It was found that this problem can be solved through addition crosslinking since no gassing of the press cushions occurs even for strong heating. Consequently, no condensation products of such gassing can precipitate on the pressing material. Additionally, odors and an associated health risk can be prevented. Consequently the quality issues can be solved and the purity requirements can be fulfilled during crosslinking and also during use in the heated presses. An additional advantage of addition crosslinking is that addition crosslinked press cushions even have higher temperature resistance, higher dynamic load bearing capability is provided in subsequent applications and the press cushions have less shrinkage. Thus, thickness tolerances in the presses can be effectively and permanently compensated.

During addition crosslinking, vinyl groups are used in the silicon polymer and a crosslinker that includes SI—H-groups. Put differently, addition crosslinking is based on bonding SI—H groups with polymers which have double bonds. Catalysts are required for this type of crosslinking. Salts or platinum complexes can be used as catalysts. Additionally, respective palladium or rhodium compounds can also be used. Addition crosslinking occurs significantly faster than crosslinking initiated by peroxides.

The professional article “Peroxide or Platinum? Cure System Considerations for Silicon Tubing Applications” by Dow Corning Corporation, written by Regina M. Malcezewski, Donald A. Jahn and William J. Schoenherr describes using addition crosslinked and peroxide crosslinked silicon polymers which are used for hoses in medical applications. The professional article points out advantages and disadvantages for both types of crosslinking, accordingly it has to be considered on a case by case basis for medical applications which of the two crosslinking variants is used.

Typically the press cushion according to the invention includes a flat contexture which can be a woven material or a knitted material. Based on this arrangement, the geometry and the fiber structure provide good shape changing capabilities and thus good cushion properties.

This is provided in particular when the silicon elastomeric material or the copolymer is provided as a coherent layer or included in threads, in particular provided in the press cushion as warp threads and/or weft threads of a fabric.

In an advantageous embodiment of the press cushion, the threads of the flat contexture include a core made from monofilament or multifilament metal threads or from monofilament or multifilament high temperature resistant plastic filaments and a jacket made from silicon elastomeric material or a copolymer. Producing the elastomeric threads is typically performed in an extruder, wherein the threads are provided with a core thread for stabilizing in their longitudinal axis. The stabilization simplifies or enables processing the threads into a flat contexture. Furthermore, the threads can have high elasticity in a direction transversal to their longitudinal axis due to the high tension strength in longitudinal direction. The cushion properties are additionally improved accordingly.

It is particularly advantageous when the threads of the flat contexture have monofilament or multifilament metal threads at their outer enveloping surface which metal threads are preferably embedded at least partially into the silicon elastomeric material or the copolymer and are connected in a force transmitting manner with the silicon elastomeric material or the copolymer. This interconnection between the elastomeric material and the metal threads can thus be provided on the one hand by a glue on the other hand by embedding the metal threads in the elastomeric material so that the metal threads in both cases do not unintentionally separate from the elastomeric material, for example during weaving. It is a purpose of the metal threads to provide good heat transfer between the heating plate and the press plate.

In order to increase heat conduction, the silicon elastomeric material and/or the copolymer can have a metal portion, in particular in the form of metal powder that is homogenously distributed in the silicon elastomeric material or in the copolymer, preferably copper, aluminum or bronze powder. The additive, however, must not exceed a certain amount since elasticity and flexibility of the silicon elastomeric material and/or of the copolymer are excessively impaired.

According to an advantageous embodiment of the press cushion according to the invention, the flat contexture includes a woven material which includes a thread system including threads including the silicon elastomeric material and/or the copolymer and another thread system including monofilament or multifilament metal threads, in particular copper or brass threads. Weaving both thread systems together can provide the cushion properties through the silicon elastomeric material and/or copolymer and also good heat conductivity between the heating plate and the press plate.

An advantageous embodiment of the press cushion is characterized in that the press cushion is provided on one surface or on both opposite surfaces with a full surface cover, preferably configured as a coating or a foil, wherein a friction coefficient of the cover is preferably between 0.01 and 0.5. An option for the cover material in this case could be PTFE (polytetrafluorethylen). This type of cover often used for so-called high pressure cushions, e.g. press cushions for producing electronic circuit boards. The additional surface coating shall prevent the press cushion from sticking together with the heating plate and/or the press plate and shall thus facilitate a longer service life for the press cushion. This is particularly advantageous in high pressure multilevel heating presses since very high pressing times are provided under high pressure in this case. Heating and cooling the press arrangement under high pressure generates a longitudinal extension or longitudinal shrinkage of the heating plates and press plates which impacts cushions arranged there between. Therefore it is important that the surface configuration of the cushions has a lower friction coefficient which increases service life of the press cushions and furthermore a generation of rub off, this means particles of the press cushion material, is prevented which is important since clean room conditions have to be maintained when manufacturing printed circuit boards.

Advantageously, the cover shall be firmly connected with the rest of the press cushion through a glue, advantageously through a full surface glue layer, wherein the glue or the glue layer is high temperature resistant. The term high temperature resistant in the sense of the application is a resistance up to 170° C., advantageously up to 180° C. further advantageously up to 200° C.

In closing, it is appreciated that the press cushions according to the invention are advantageously used in heating presses with re-cooling. This type of heating presses is advantageously used for producing printed circuit boards which are used for electrical and electronics applications. Since the addition crosslinked press cushions do not generate gas emissions, a precipitation on the printed circuit boards is prevented. Precipitation on these very sensitive components can lead to damages and malfunctions and is accordingly not acceptable.

### BRIEF DESCRIPTION OF THE DRAWINGS

The invention described supra is now described in more detail based on two embodiments with reference to drawing Figures, wherein:

FIG. 1 illustrates a cross section of a press cushion for a single level short cycle press.

FIG. 2 illustrates a cross section of a press cushion for a multilevel high pressure press.

### DETAILED DESCRIPTION OF THE INVENTION

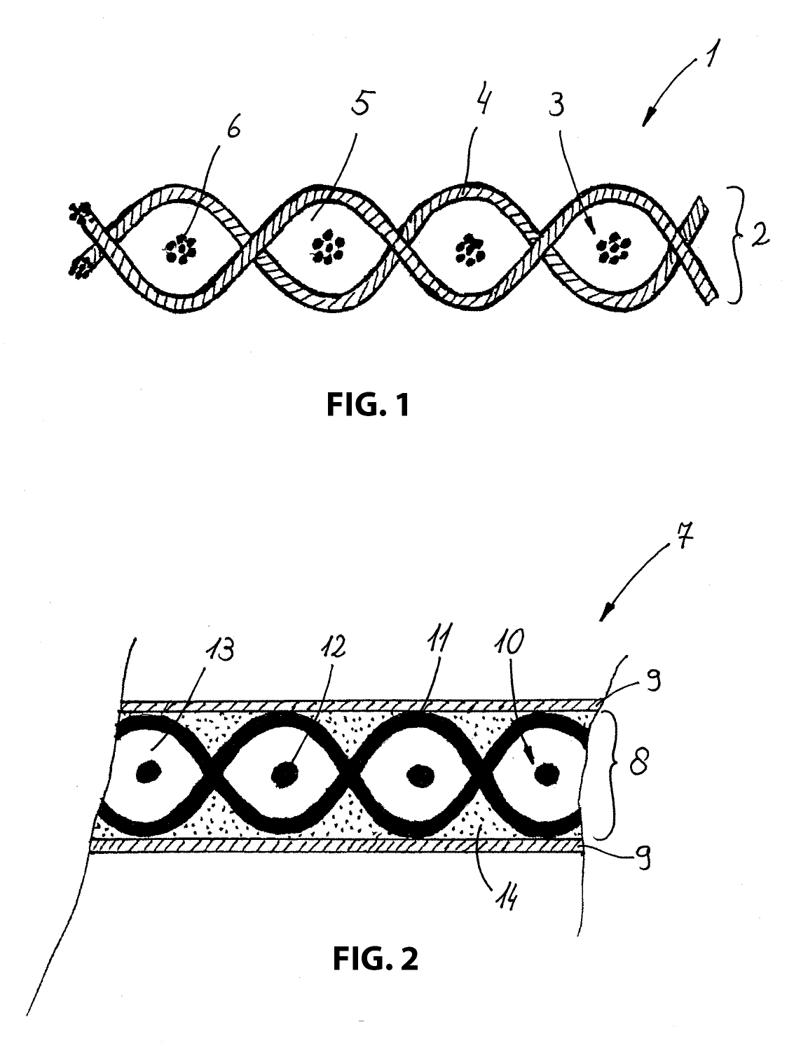

The embodiment of the press cushion 1 according to the invention illustrated in FIG. 1 includes a flat contexture 2 which includes weft threads 3 and warp threads 4. The weft threads 3 include a thread jacket material 5 made from addition crosslinked silicon elastomeric material and a core thread 6, wherein the core thread 6 is for example made from stranded copper threads. It is an object of the core thread 6 to facilitate weaving the threads together and on the other hand to provide high elasticity of the elastomeric material arranged in the thread transversal to its longitudinal axis. In this case, the core thread 6 predetermines stability in longitudinal direction. Warp threads 4 made from brass extend perpendicular to the fiber jacket 5 made from silicon elastomeric material wherein the brass warp threads increase heat transfer.

FIG. 2 illustrates another embodiment of a press cushion 7. The press cushion is made from a flat contexture 8 and a cover 9. The flat contexture 8 includes weft threads 10 and warp threads 11. The weft threads 10 include a core thread 12 made from high temperature resistant fiber filaments made from aromatic polyamide (Kevlar®) and a fiber jacket 13 made from addition crosslinked silicon elastomeric material. The warp threads 11 are multifilaments and are not made from metal in this case but from the aromatic polyamide (Kevlar®). The cover 9 is arranged at the opposite sides of the flat contexture. The cover 9 is made for example from a PTFE foil with a lower friction coefficient. A high temperature resistant glue, in particular in the form of a glue layer 14 applied to the full surface of the press cushion 7, is used for attaching the cover 9 at the woven “base grid” of the press cushion 7.

### REFERENCE NUMERALS AND DESIGNATIONS

1 Press cushion
2 Flat contexture
3 Weft thread
4 Warp thread
5 Fiber jacket
6 Core thread
7 Press cushion
8 Flat contexture
9 Cover
10 Weft thread
11 Warp thread
12 Core thread
13 Fiber jacket
14 Glue

What is claimed is:

1. A press cushion for a one level or multi level heating press, comprising:
a flat contexture made from threads or fibers; and
a silicon elastomeric material made by crosslinking silicon rubber or a copolymer made by crosslinking silicon rubber and fluor silicon rubber or a copolymer made by crosslinking silicon rubber and fluor rubber,
wherein the silicon elastomeric material or the copolymer are addition crosslinked.

2. The press cushion according to claim 1, wherein the flat contexture is a woven material or a knitted material.

3. The press cushion according to claim 1, wherein the silicon elastomeric material or the copolymer is provided in the press cushion as a coherent layer or included in threads that are in particular provided as warp threads or weft threads of a fabric.

4. The press cushion according to claim 3, wherein the threads of the flat contexture include
a core made from monofilament or multifilament metal threads or made from monofilament or multifilament high temperature resistant plastic laminates, and
a jacket made from silicon elastomeric material or a copolymer.

5. The press cushion according to claim 3,
wherein threads of the flat contexture include monofilament or multifilament metal threads at their outer enveloping surface,
wherein the threads of the flat contexture are at least partially embedded in the silicon elastomeric material or the copolymer and connected with the silicon elastomeric material or the copolymer in a force transmitting manner.

6. The press cushion according to claim 1,
wherein the silicon elastomeric material or the copolymer includes a metal portion,
wherein the metal portion is provided as a metal powder that is homogeneously distributed in the silicon elastomeric material or in the copolymer,
wherein the metal powder is provided as copper, aluminum or bronze powder.

7. The press cushion according to claim 1,
wherein the flat contexture is a woven material,
wherein the woven material includes a thread system including threads including the silicone elastomeric material or the copolymer, and
wherein the woven material includes another thread system including monofilament or multifilament metal threads, in particular copper or brass threads.

8. The press cushion according to claim 1,
wherein the press cushion is provided at one surface or at both opposite surfaces with a full surface cover provided as a coating or a foil,
wherein a friction coefficient of the full surface cover is between 0.01 and 0.5.

9. The press cushion according to claim 8,
wherein the full surface cover is firmly connected with the press cushion through a glue in a full surface glue layer,
wherein the glue or the glue layer is high temperature resistant.

10. A method of using a press cushion according to claim 1, comprising the steps:
using the press cushion in heating presses with re-cooling configured as multilevel high pressure presses, and
using the heating presses for producing circuit boards for electrical and electronic applications.

11. A press cushion for a one level or multi level heating press, comprising:
a flat contexture made from threads or fibers; and
a silicon elastomeric material made by crosslinking silicon rubber and a copolymer made by crosslinking silicon rubber and fluor silicon rubber and a copolymer made by crosslinking silicon rubber and fluor rubber,
wherein the silicon elastomeric material and the copolymer are addition crosslinked.
